(19) United States
(12) Patent Application Publication
(10) Pub. No.: US 2007/0278523 A1
(43) Pub. Date: Dec. 6, 2007

(54) Structure and a method for monolithic integration of HBT, depletion-mode HEMT and enhancement-mode HEMT on the same substrate

(75) Inventors: Heng-Kuang Lin, Tao Yuan Shien (TW); Chia-Liang Chao, Tao Yuan Shien (TW); Ming-Chang Tu, Tao Yuan Shien (TW); Tsung-Chi Tsai, Tao Yuan Shien (TW); Yu-Chi Wang, Tao Yuan Shien (TW)

Correspondence Address: BACON & THOMAS, PLLC, 625 SLATERS LANE, FOURTH FLOOR, ALEXANDRIA, VA, 22314, US

(73) Assignee: WIN Semiconductors Corp., Tao Yuan Shien (TW)

(21) Appl. No.: 11/446,206

(22) Filed: Jun. 5, 2006

(51) Int. Cl. H01L 29/739

(52) U.S. Cl. 257/194

(57) ABSTRACT

An epitaxial layers structure and a method for fabricating HBTs and HEMTs on a common substrate are disclosed. The epitaxial layers comprise generally a set of HBT layers on the top of a set of HEMT layers. The method can be used to fabricate HBT, E-mode HEMT and D-mode HEMT as well as passive devices, that enabling monolithic integration of a significant number of devices on a common substrate by a cost-effective way.

### FIELD OF THE INVENTION

The present invention relates in general to integrated circuits made of III-V compound semiconductors and, in particular, to a stacked-layer structure containing HBT layers on the top of HEMT layers, and to a method for fabricating HBTs, depletion-mode pHEMTs, enhancement-mode pHEMTs as well as passive devices, that enables monolithic integration of a significant number of devices on a common substrate.

### BACKGROUND OF THE INVENTION

Integration of multifunction circuit devices, which include more than one device type on a common substrate, in certain applications (such as microwave, millimeter wave, and optoelectronic application) not only increases the performance of the integrated circuits, but also provides a practical solution to achieve greater cost and space reduction. For example, by integrating heterojunction bipolar transistors (HBTs) and heterojunction field-effect transistors (HFETs), such as high-electron-mobility transistors (HEMTs) in general, and pseudomorphic HEMT (pHEMTs) in particular, the low-noise advantages of HEMTs together with the high-power and high-linearity features of HBTs provide microwave circuits with lower noise and higher power than those realized by separately fabricating HEMTs and HBTs in known baseline fabrication techniques and then combining into hybrid circuits.

HBT devices conventionally yield excellent capability for power amplifiers, voltage control oscillator (VCO) and mixer applications with single supply voltage. However, HBT devices are known to be handicapped with high turn-on voltage, leading to an undesirable high reference voltage in power amplifiers, which is not favorable in the product trend. On the other hands, depletion-mode (D-mode) HEMT devices are excellent candidates to replace PIN diodes for antenna switches with significant higher switching speed and lower power consumption. Besides, the D-mode HEMT device can also be used as the biasing circuitry in HBT power amplifier to supplement its disadvantage of high turn-on voltage. In contrast to the HBT device and the D-mode HEMT, enhancement-mode (E-mode) HEMT may be the best candidate for low-noise amplifiers with single supply voltage and low-supply-voltage power amplifiers used for applications in a RF front-end subsystem. In addition, the E-mode HEMT in combination with D-mode HEMT can be implemented as digital logic circuits, such as decoder in antenna switch, which in conventional technology requires an additional CMOS chip to fulfill the same function. However, current semiconductor fabrication techniques are limited in the ability to fabricate more than one device type on a common substrate. Therefore, the development of technologies for monolithic integration for HBT and E/D-mode HEMT devices, as well as other passive devices (such as capacitors, diodes, and resistors) will represent a significant step toward system-on-a-chip to achieve higher functionality level and enhanced performance but with smaller chip size and reduced cost.

### SUMMARY OF THE INVENTION

It is an object of the present invention to provide a stacked-layer structure containing HBT layers on the top of HEMT layers that facilitates monolithic integration of the HBT and the HEMT of different operation modes.

It is also an object of the present invention to provide a method for fabricating HBTs and HEMTs of different operation modes on the same substrate in a cost-effective way.

In order to achieve the above-described objects, the present invention generally consists of HEMT layers with HBT layers thereon, formed on a substrate. The substrate is preferably a semi-insulating GaAs substrate, or other suitable substrates for epitaxial growth of the stacked-layer structure thereon. After providing the substrate, the stacked-layer structure are then grown on the substrate by well-known technologies, such as molecular beam epitaxy (MBE), or metalorganic chemical vapor deposition (MOCVD). The stacked-layer structure generally consists of two set of layers: the first set of layers is the HEMT layers, and the second set is the HBT layers. An etching stop layer, which may be an InGaP layer, is inserted between these two sets of layers in order to facilitate the fabrication processes for the HBT and the HEMT devices.

In addition, the present invention provides a method for producing a mixed integrated circuit of HBT, D-pHEMT, and E-pHEMT on a common substrate. It comprises the steps of:

growing a stacked layer structure with HBT atop of p-HEMT devices;

processing top HBT materials into the devices in the beginning;

isolating the devices using both wet etch and ion implantation;

processing bottom pHEMT materials into devices in which E-mode gate metal was deposited and alloyed first, followed by D-mode gate metal, and passive devices were fabricated in the final.

It should be noted that the alloying is not only for E-mode gate but also for ohmic contacts.

### BRIEF DESCRIPTION OF DRAWINGS

FIG. 1 is an embodiment of the epitaxial layer structure of the present invention for fabricating HBTs and HEMTs on the same substrate.

FIG. 2 is a schematic of process flow of the method of the present invention for fabricating integrated HBTs, D-mode pHEMTs and E-mode pHEMTs on a common substrate.

FIG. 3 shows a cross-sectional view of an embodiment of the present invention for the integrated HBT, D-mode pHEMT, E-mode pHEMT, and the passive devices on a common substrate.

FIG. 4 is a schematic illustrating the difference in the E-mode and D-mode pHEMT devices.

FIG. 5. is a schematic of the mesa resistor of the present invention, in which a recess gate is fabricated on the top of the mesa resistor, hence increasing the resistance of the mesa resistor and thereby saving space in circuit design.

### DETAILED DESCRIPTION OF THE INVENTION

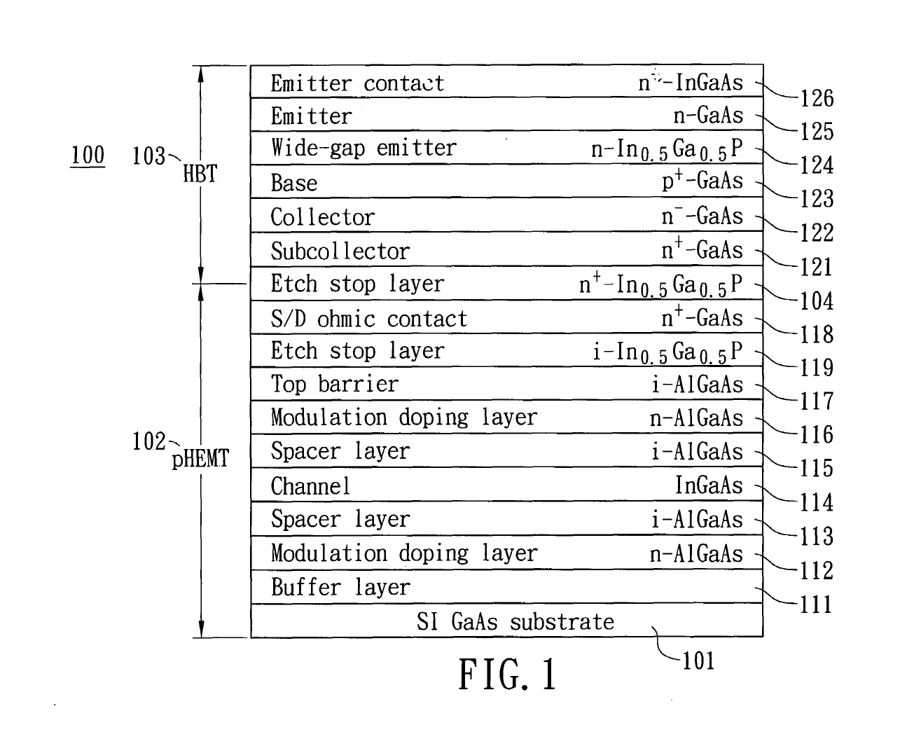

FIG. 1 illustrates the epitaxial layer structure used for the invention 100. It is basically a vertically stacked-layer structure, which generally consists of HEMT layers with HBT layers thereon, formed on a substrate 101. The substrate is preferably a semi-insulating GaAs substrate, or other suitable substrates for epitaxial growth of the stacked-layer structure thereon. After providing the substrate 101, the stacked-layer structure are then grown on the substrate 101 by well-known technologies, such as molecular beam epitaxy (MBE), or metalorganic chemical vapor deposition (MOCVD). The stacked-layer structure generally consists of two set of layers: the first set of layers is the HEMT layers 102, and the second set is the HBT layers 103. An etching stop layer 104, which may be an InGaP layer, is inserted between these two sets of layers in order to facilitate the fabrication processes for the HBT and the HEMT devices.

As a embodiment of the invention, the HEMT layers 102 can be designed as a pseudomorphic HEMT (pHEMT) structure, which further consists of a buffer layer 111, a bottom modulation doped AlGaAs layer 112, an undoped AlGaAs bottom spacer layer 113, a InGaAs channel layer 114, an undoped AlGaAs top spacer layer 115, a top modulation doped AlGaAs layer 116, an undoped AlₓGa₁₋ₓAs top barrier layer 117 (wherein x=0 to 0.33), and a heavily doped GaAs contact layer 118 for source/drain ohmic contacts. A thin InGaP etching stop layer 119 is also inserted between the top barrier layer 117 and the contact layer 118 in order to facilitate the fabrication of gate recess of the pHEMT. The HBT layers 103 can be designed as an npn type device, which further consists of a n⁺-GaAs subcollector layer 121, a n-GaAs collector layer 122, a p⁺-GaAs base layer 123, a wide-band-gap emitter layer 124, (which may be a n-In_{0.5}Ga_{0.5}P layer), a n-GaAs emitter layer 125, and a n⁺-InGaAs emitter contact layer 126.

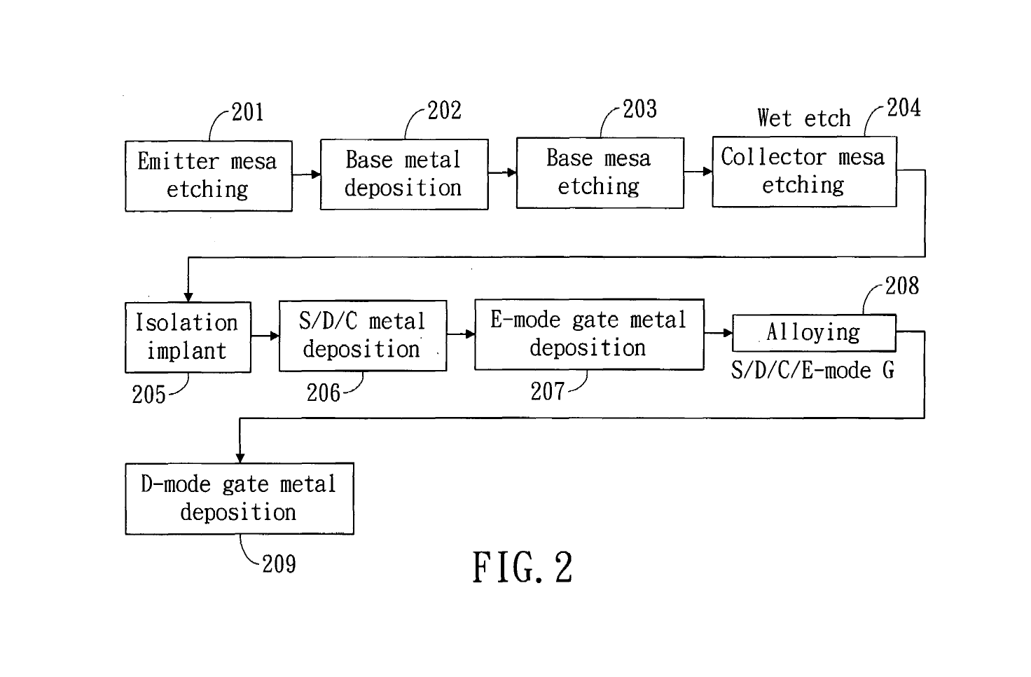

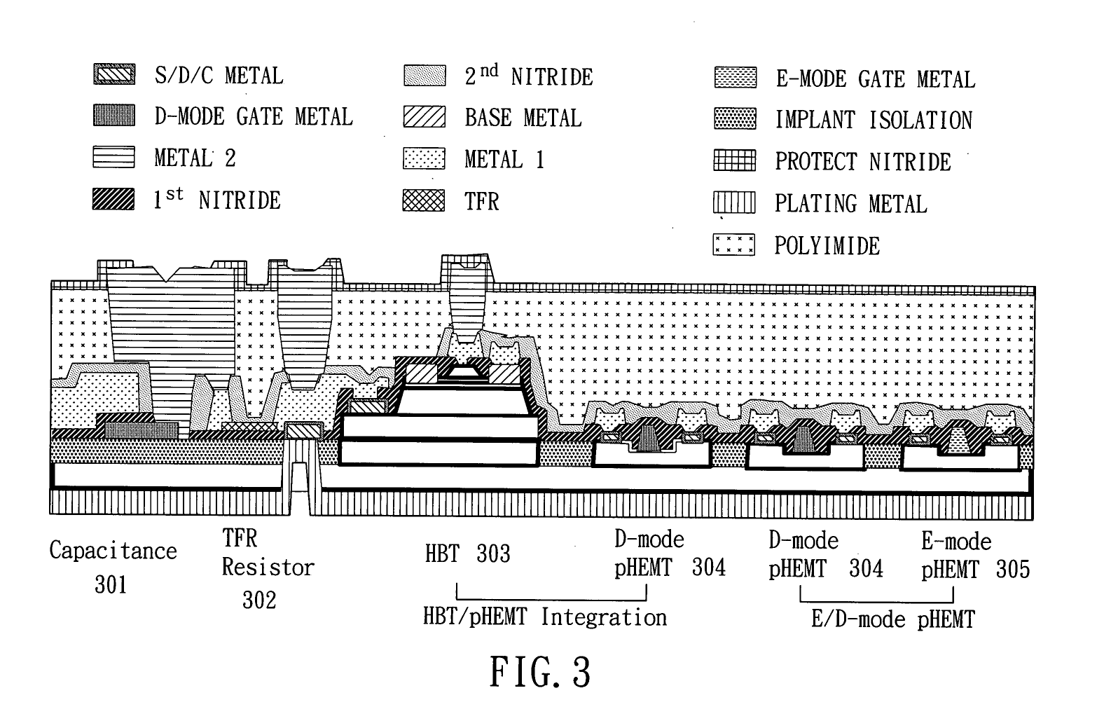

After the epitaxial growth of the stacked-layer structure 102-126, the wafer can then be processed to fabricate integrated HBT and HEMT devices. FIG. 2 illustrates a schematic of process flow of the method for fabricating integrated HBT, D-mode pHEMT and E-mode pHEMT as well as a passive device on a common substrate. A cross-sectional view for the integrated HBT 303, D-mode pHEMT 304, E-mode pHEMT 305, and the passive devices, such as the capacitance 301 and the TFR Resistor 302, is shown in FIG. 3. The device fabrication starts with processing HBT device. Emitter mesa is first defined in step 201 by using standard photolithography and etching processes. After the formation of emitter mesa, base metal is deposited in step 202, followed by etching to form base mesa in step 203. Collector mesa is form in step 204 by wet chemical etching. Of particular importance in the step 204 is the InGaP layer 104, which is known to have a very high etching selectivity with GaAs and is therefore utilized as an etching stop layer for the collector mesa definition and as a buffer layer for separating the HBT from the pHEMT device in views of process considerations. In step 205, ion implantation is utilized to further isolate the HBT not only from the following pHEMT devices, but also from other passive devices, such as diodes, capacitors or resistors.

After depositing collector, source, and drain ohmic metals in step 206, and gate metal for the E-mode pHEMT in step 207, then alloy all of them in step 208 to achieve either good ohmic contacts of the collector/source/drain metal or controlled effective thickness of the top barrier of the E-mode pHEMT In step 209, gate metal for the D-mode pHEMT is deposited, which is also the final step for the fabrication of active devices.

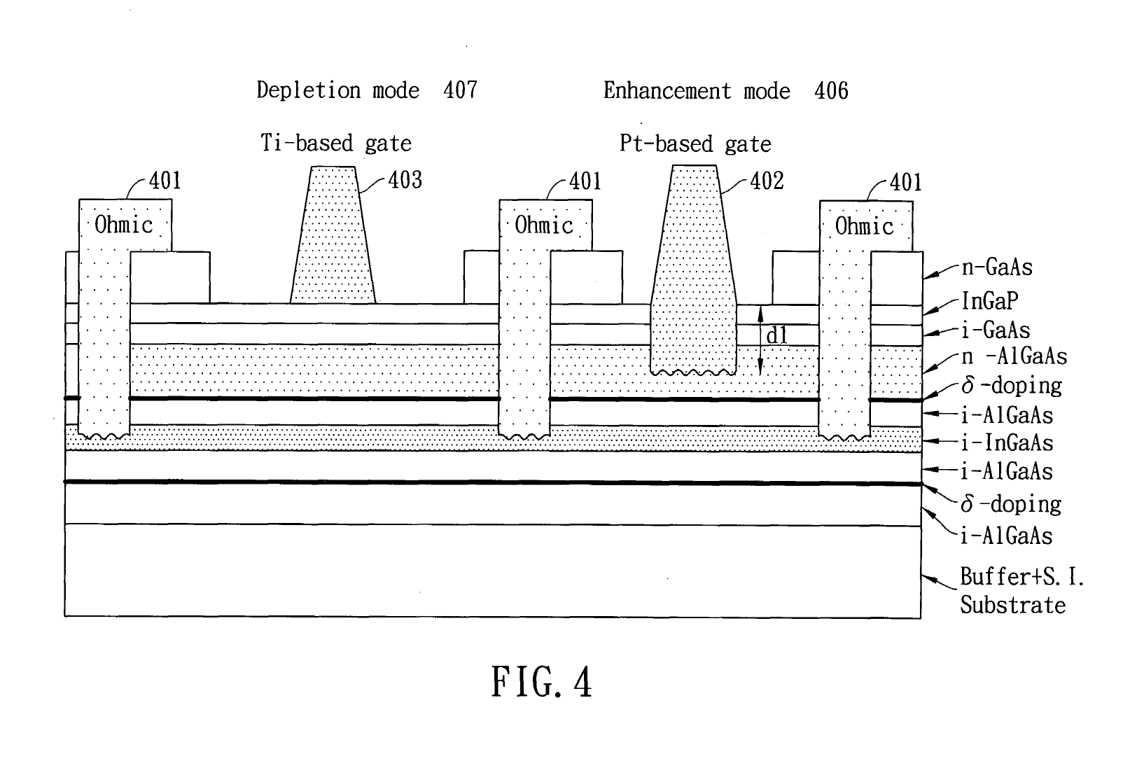

A schematic shown in FIG. 4 is given to illustrate the difference in the E-mode and D-mode pHEMT devices 406, 407. It is noteworthy that both the source/drain/collector metals 401 and the E-mode gate metal 402, which may be a Pt-based metal, are alloyed concurrently in step 207. Because the alloying condition in this step determine the penetration depth d1 of the Pt-based gate metal and hence the effective top barrier thickness of pHEMTs for E-mode operations, a suitable metal compound or alloy for the source/drain/collector metals 401 should be chosen so that both good ohmic contacts and a controlled top barrier thickness can be achieved via the same alloying condition. The D-mode gate metal 403, which may be a Ti-based metal, is then deposited in step 208 to form a Schottky gate for the pHEMT operating in depletion modes.

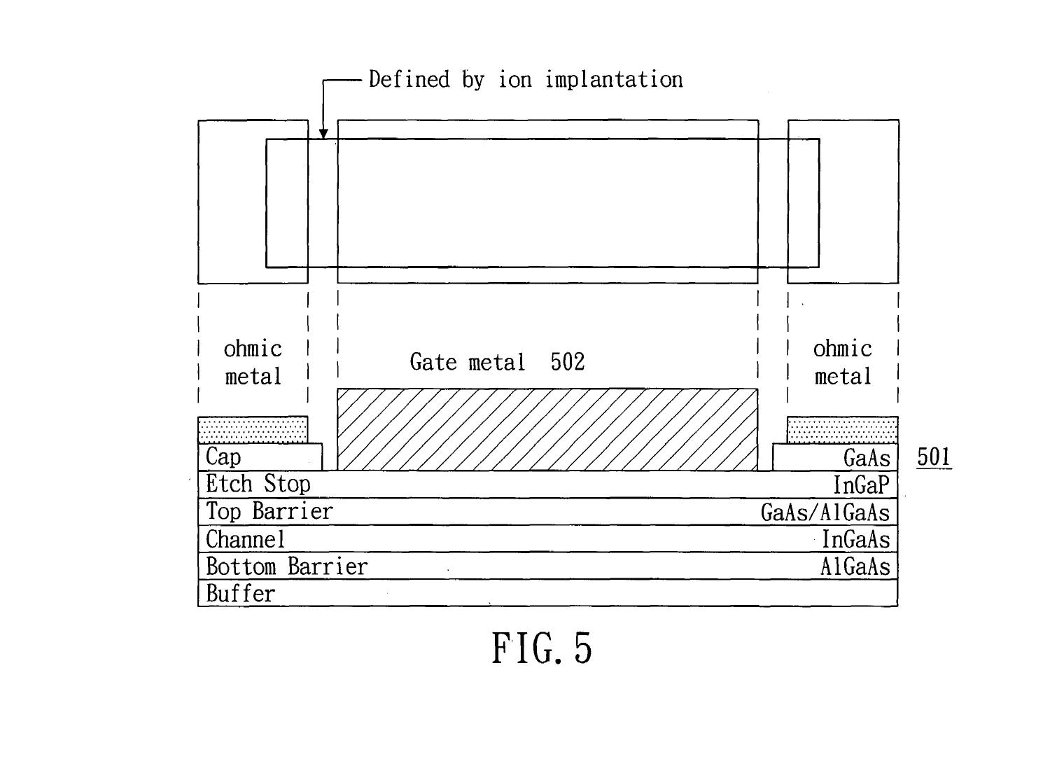

After the fabrication of active devices, passive devices are initiated, including capacitors, diodes, and resistors, depending specifically on applications. The capacitor can be formed by the 1st and 2nd nitride with controlled thickness. The diodes can be made, for example, by depositing a Schottky gate on the collector layer. The resistor may either be a thin-film resistor (TFR), or a mesa resistor made of a tantalum nitride (TaN) film atop a pHEMT mesa. In order to increase the resistance of the mesa resistor 501 and thereby saving space in circuit design, a recess gate 502 may be fabricated on the top of the mesa resistor 501, as shown in FIG. 5.

Accordingly, the present invention has following advantages:
1. An advantage of the method in the present invention is that the fabrication of collector, source, drain ohmic contacts, and E-mode gate metal at the same stage, which considerably reduces the process steps as well as the numbers of mask, and hence the process complexity.
2. The present invention eliminates the generation of additional parasitic capacitance in the p-HEMT device. This additional parasitic capacitance will severely degrade high frequency performance.
3. The present invention provides a practical solution for mass production and avoids additional processing steps and sophisticated clean procedures, which are required in selective re-grown MBE technique. These processes or procedures lead to low-yield and high-cost fabrication.
4. The present invention is more flexible in device layer design than the method of planar HBT/MESFET device, in which additional parasitic capacitance is also an issue.
5. InGaP etch stop layer provides process easiness when defining HBT device due to its high selectivity with GaAs.
6. Implant isolation instead of wet etch for device isolation described herein avoids further aggravation of surface morphology.

As disclosed in the above paragraphs, it could be appreciated that the present invention is new and useful.

What is claimed is:

1. A structure of semiconductor epitaxial layers for the fabrication of integrated HBTs and pHEMTs of different modes on a common substrate comprising: a substrate;
a first set of epitaxial layers on top of the substrate, forming pHEMT layers; a second set of epitaxial layers on top of the first set of epitaxial layers, forming HBT layers; and
an etching stop layer inserted between the first set and the second set of layers.

2. The structure of claim 1 wherein the first set of epitaxial layers further comprises a buffer layer; a channel layer; a modulation doped layer, a top barrier layer, and a source/drain contact layer, forming a set of pHEMT layers.

3. The structure of claim 2 wherein the channel layer in the set of pHEMT layers is an InGaAs layer.

4. The structure of claim 2 wherein the modulation doped layer in the set of pHEMT layers is a modulation doped AlGaAs layer.

5. The structure of claim 2 wherein the top barrier layer in the set of pHEMT layers is an undoped AlₓGa₁₋ₓAs layer, wherein x=0 to 0.33.

6. The structure of claim 2 wherein the source/drain contact layer in the set of pHEMT layers is a n-type heavily doped GaAs layer with a doping concentration higher than 1×10¹⁸ cm⁻³.

7. The structure of claim 2 further comprises a thin etching stop layer inserted between the top barrier layer and the source/drain contact layer.

8. The structure of claim 7 wherein the thin etching stop layer is an undoped InGaP layer, or other materials with high etching selectivity with those of the top barrier layer and the source/drain contact layer.

9. The structure of claim 1 wherein the second set of epitaxial layers further comprises a subcollector layer; a collector layer; a base layer, a wide-gap emitter layer, an emitter transition layer and an emitter contact layer, forming a set of HBT layers.

10. The structure of claim 9 wherein the subcollector layer in the set of HBT layers is an n-type heavily doped GaAs layer with a doping concentration higher than 5×10¹⁸ cm⁻³.

11. The structure of claim 9 wherein the collector layer in the set of HBT layers is an n-type lightly doped GaAs layer with a doping concentration lower than 1×10¹⁷ cm⁻³.

12. The structure of claim 9 wherein the base layer in the set of HBT layers is a p-type heavily doped GaAs layer with a doping concentration higher than 1×10¹⁹ cm⁻³.

13. The structure of claim 9 wherein the wide-gap emitter layer in the set of HBT layers is an n-type InGaP layer.

14. The structure of claim 9 wherein the emitter transition layer in the set of HBT layers is a n-type heavily doped GaAs layer with a doping concentration higher than 5×10 ¹⁸ cm⁻³.

15. The structure of claim 9 wherein the emitter contact layer in the set of HBT layers is a n-type heavily doped InGaAs layer with a doping concentration higher than 1×10¹⁹ cm⁻³, or other heavily doped lower band gap materials for facilitating metal contacts.

16. The structure of claim 1 wherein the etching stop layer is an n-type heavily doped InGaP layer, or other heavily doped materials with high etching selectivity with the GaAs.

17. A method for fabricating integrated HBT and pHEMT devices comprising the steps of:
growing the epitaxial layer structure as described in claim 1;
processing the second set of epitaxial layers of the structure into HBT devices;
defining and isolating devices using both wet etching and ion implantation; and
fabricating the first set of epitaxial layers of the structure into pHEMT devices.

18. The method of claim 17 wherein the step of processing further comprises steps of:
emitter mesa etching; base metal deposition; base mesa etching; and collector mesa etching.

19. The method of claim 17 wherein said pHEMT devices, in the step of fabricating, include E-mode pHEMT and D-mode pHEMT.

20. The method of claim 17 wherein the step of fabricating further comprises steps of:
collector/source/drain metal deposition; E-mode gate metal deposition, alloying and D-mode gate metal deposition.

21. The method of claim 20 wherein the E-mode gate metal is a Pt-based metal.

22. The method of claim 20 wherein the D-mode gate metal is a Ti-based metal.

23. The method of claim 20 wherein the condition of the step of alloying is specifically chosen to achieve good ohmic contact for the deposited collector/source/drain metal and controlled effective top barrier thickness for the deposited E-mode gate metal
